(19) United States
(12) Patent Application Publication
(10) Pub. No.: US 2025/0132264 A1
(43) Pub. Date: Apr. 24, 2025

(54) GLASS CORES WITH EMBEDDED POWER DELIVERY COMPONENTS

(71) Applicant: Intel Corporation, Santa Clara, CA (US)

(72) Inventors: Huong Thu Do, Chandler, AZ (US); Nicholas Steven Haehn, Scottsdale, AZ (US); Brandon Christian Marin, Gilbert, AZ (US); Mitchell Ian Page, Mesa, AZ (US); Erhan Atci, Maricopa, AZ (US)

(73) Assignee: Intel Corporation, Santa Clara, CA (US)

(21) Appl. No.: 19/005,018

(22) Filed: Dec. 30, 2024

(51) Int. Cl. H01L 23/538; H01L 23/15; H01L 25/18; H10D 1/20

(52) U.S. Cl. CPC H01L 23/5386; H01L 25/18; H10D 1/20; H01L 23/15

(57) ABSTRACT

Glass cores with embedded power delivery components are disclosed. An example apparatus includes a glass layer including an opening, a dielectric material within the opening, a first cluster of inductors extending through the dielectric material, and a second cluster of inductors extending through the dielectric material, the second cluster spaced apart from the first cluster, the dielectric material extending continuously from around the first cluster to around the second cluster.

### BACKGROUND

Integrated circuit (IC) chips and/or semiconductor dies are routinely connected to larger circuit boards such as motherboards and other types of printed circuit boards (PCBs) via a package substrate. As IC chips and/or dies reduce in size and interconnect densities increase, alternatives to traditional substrate layers are being developed to provide stable transmission of high-frequency data signals between different circuitry and/or increased power delivery. One option being pursued is the implementation of package substrates with glass cores. Generally, glass core implementations offer several advantages compared to implementations with conventional epoxy cores, including a higher plated through-hole (PTH) density, lower signal losses, and lower total thickness variation.

### BRIEF DESCRIPTION OF THE DRAWINGS

FIG. 1 illustrates an example integrated circuit (IC) package constructed in accordance with teachings disclosed herein.

FIG. 2 illustrates a perspective view of an example first glass core that can be used with the example IC package of FIG. 1.

FIG. 3 is a top view of the example first glass core of FIG. 2 including a power delivery portion.

FIG. 4 is a cross-sectional side view of the example first glass core of FIGS. 2 and 3.

FIG. 5 illustrates a perspective view of an example second glass core that can be used with the example IC package of FIG. 1.

FIGS. 6A and 6B are cross-sectional side views of the example second glass core of FIG. 5 including a power delivery portion.

FIG. 7 is a top view of the example second glass core of FIGS. 5, 6A, and 6B.

FIG. 8 is a cross-sectional side view of an example third glass core similar to the example second glass core of FIG. 5.

FIG. 9 is a top view of a wafer including dies that may be included in an IC package constructed in accordance with teachings disclosed herein.

FIG. 10 is a cross-sectional side view of an IC device that may be included in an IC package constructed in accordance with teachings disclosed herein.

FIG. 11 is a cross-sectional side view of an IC device assembly that may include an IC package constructed in accordance with teachings disclosed herein.

FIG. 12 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

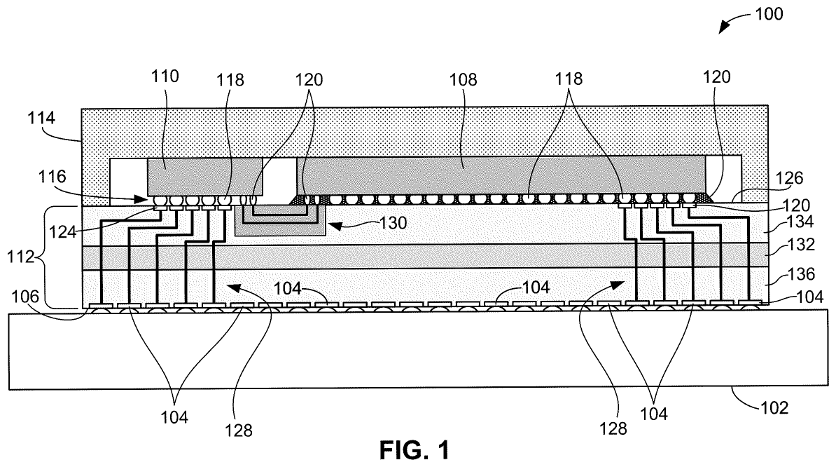

FIG. 1 illustrates an example integrated circuit package 100 constructed in accordance with teachings disclosed herein. In the illustrated example, the IC package 100 is electrically coupled to an underlying substrate 102 via an array of contacts 104 on a package mounting surface 106 (e.g., a bottom surface, an external surface) of the package. In some examples, the substrate 102 can be implemented by a package substrate or a printed circuit board (PCB). In the illustrated example, the contacts 104 are represented as pads or lands. However, in some examples, the IC package 100 may include balls, pins, and/or any other type of contact, in addition to or instead of the pads or lands shown to enable the electrical coupling of the IC package 100 to the substrate 102. In this example, the IC package 100 includes two dies 108, 110 (e.g., silicon dies, semiconductor dies, etc.), sometimes also referred to as chips or chiplets, that are mounted to a package substrate 112 and enclosed by a package lid 114 (e.g., a mold compound, an integrated heat spreader (IHS)). Thus, the package substrate 112 is an example means for supporting a semiconductor die. While the example IC package 100 of FIG. 1 includes two dies 108, 110, in other examples, the IC package 100 may have only one die or more than two dies. In some examples, one of the dies 108, 110 (or a separate die) is embedded in the package substrate 112. The dies 108, 110 can provide any suitable type of functionality (e.g., data processing, memory storage, etc.). In some examples, one or both of the dies 108, 110 are implemented by a die package including multiple dies arranged in a stacked formation. For example, the second die 110 can include a stack of Dynamic Random Access Memory (DRAM) die arranged on top of a memory controller die to form a memory die stack.

As shown in the illustrated example, each of the dies 108, 110 is electrically and mechanically coupled to the package substrate 112 via corresponding arrays of interconnects 116. In FIG. 1, the interconnects are shown as bumps. The interconnects 116 can include solder joints, micro bumps, combinations of metallic (e.g., copper) pillars and solder, etc. In other examples, the interconnects 116 may include directly bonded or “hybrid bonded” metallic interconnects. In other examples, the interconnects 116 may be any other type of electrical connection in addition to or instead of the bumps shown (e.g., balls, pins, pads, pillars, wire bonding, etc.). The electrical connections between the dies 108, 110 and the package substrate 112 (e.g., the interconnects 116) are sometimes referred to as first level interconnects. By contrast, the electrical connections between the IC package 100 and the substrate 102 (e.g., the contacts 104) are sometimes referred to as second level interconnects. In some examples, one or both of the dies 108, 110 may be stacked on top of one or more other dies and/or an interposer. In such examples, the dies 108, 110 are coupled to the underlying die and/or interposer through a first set of first level interconnects and the underlying die and/or interposer may be connected to the package substrate 112 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 116 of the first level interconnects include two different types of bumps corresponding to core bumps 118 and bridge bumps 120. As used herein, the core bumps 118 are bumps on the dies 108, 110 through which electrical signals pass between the dies 108, 110 and components external to the IC package 100. More particularly, as shown in the illustrated example, when the dies 108, 110 are mounted to the package substrate 112, the core bumps 118 are physically connected and electrically coupled to contact pads 124 on a die mounting surface 126 (e.g., an upper surface, a top surface, etc.) of the package substrate 112. The contact pads 124 on the die mounting surface 126 of the package substrate 112 are electrically coupled to the contacts 104 on the package mounting surface 106 (e.g., the bottom, external surface) of the package substrate 112 (e.g., a surface opposite the die mounting surface 126) via internal interconnects 128 within the package substrate 112. As a result, there is a continuous electrical signal path between the core bumps 118 of the dies 108, 110 and the contacts 104 mounted to the substrate 102 that pass through the contact pads 124 and the internal interconnects 128 provided therebetween. As shown, the package mounting surface 106 and the die mounting surface 126 define opposing outer surfaces of the package substrate 112. While both surfaces are outer surfaces of the package substrate, the die mounting surface 126 is sometimes referred to herein as an internal or inner surface relative to the IC package 100. By contrast, in this example, the package mounting surface 106 is an outer or exterior surface of the IC package 100.

As used herein, the bridge bumps 120 are bumps on the dies 108, 110 through which electrical signals pass between different ones of the dies 108, 110 within the IC package 100. Thus, as shown in the illustrated example, the bridge bumps 120 of the first die 108 are electrically coupled to the bridge bumps 120 of the second die 110 via an interconnect bridge 130 (e.g., a silicon-based interconnect bridge, an interconnect die, an embedded interconnect bridge (EMIB)) embedded in the package substrate 112. As represented in FIG. 1, core bumps 118 are typically larger than bridge bumps 120. In some examples, interconnect bridge 130 and the associated bridge bumps 120 are omitted.

In some examples, the IC package 100 includes additional passive components, such as surface-mount resistors, capacitors, and/or inductors disposed on the package mounting surface 106 of the package substrate 112 and/or the die mounting surface 126 of the package substrate 112.

In FIG. 1, the package substrate 112 of the example IC package 100 includes a glass core 132 (e.g., a glass substrate, a glass layer, etc.) between two separate build-up regions 134, 136 (also referred to herein as build-up layers, etc.). In some examples, the glass core 132 includes at least one of: aluminosilicate, borosilicate, alumino-borosilicate, silica, and/or fused silica. In some examples, the glass core 132 includes one or more additives including: aluminum oxide (Al₂O₃), boron trioxide (B₂O₃), magnesia oxide (MgO), calcium oxide (CaO), stoichiometric silicon oxide (SrO), barium oxide (BaO), stannic oxide (SnO₂), nickel alloy (Na₂O), potassium oxide (K₂O), phosphorus trioxide (P₂O₃), zirconium dioxide (ZrO₂), lithium oxide (Li₂O), titanium (Ti), and/or zinc (Zn). In some examples, the glass core 132 includes silicon and oxygen. In some examples, the glass core 132 includes silicon, oxygen and/or one or more of aluminum, boron, magnesium, calcium, barium, tin, sodium, potassium, strontium, phosphorus, zirconium, lithium, titanium, and/or zinc. In some examples, the glass core 132 includes at least 23 percent silicon by weight and at least 26 percent oxygen by weight. In some examples, the glass core is a layer of glass including silicon, oxygen, and aluminum. In some examples, the glass core 132 includes at least 23 percent silicon by weight, at least 26 percent oxygen by weight, and at least 5 percent aluminum by weight.

In some examples, the glass core 132 is an amorphous solid glass layer. In some examples, the glass core 132 is a layer of glass that does not include an organic adhesive or an organic material. In some examples, the glass core 132 is a solid layer of glass having a rectangular shape in plan view. In some examples, the glass core 132, as a glass substrate, includes at least one glass layer and does not include epoxy and does not include glass fibers (e.g., does not include an epoxy-based prepreg layer with glass cloth). In some examples, the glass core 132 corresponds to a single piece of glass that extends the full height/thickness of the core. In other examples, the glass core 132 can be silicon, a dielectric material, and/or any other material(s).

In some examples, the glass core 132 has a rectangular shape that is substantially coextensive (e.g., within 10%), in plan view, with the layers above and/or below the core. In some examples, the glass core 132 has a thickness in a range of about 50 micrometers (μm) to about 1.4 millimeters (mm). In some examples, the glass core 132 can be a multi-layer glass substrate (e.g., a coreless substrate), where a glass layer has a thickness in a range of about 25 μm to about 50 μm. In some examples, the glass core 132 can have dimensions of about 10 mm on a side to about 250 mm on a side (e.g., 10 mm by 10 mm to 250 mm by 250 mm). In some examples, the glass core 132 corresponds to a rectangular prism volume with sections (e.g., vias) removed and filled with other materials (e.g., metal). Among other things, glass cores are advantageous over epoxy-based cores because glass is stiffer and, therefore, provides greater mechanical support or strength for the package substrate. Thus, the glass core 132 is an example means for strengthening the package substrate.

The build-up regions 134, 136 are represented in FIG. 1 as masses/blocks with the internal interconnects 128 extending in straight lines through the build-up regions 134, 136 (and the glass core 132). However, FIG. 1 has been simplified for the sake of clarity and purposes of explanation. In practice, the interconnects are not necessarily straight. More particularly, in some examples, the build-up regions 134, 136 are defined by alternating layers of dielectric material and layers of conductive material (e.g., a metal such as copper). The conductive (metal) layers serve as the basis for the internal interconnects 128 represented, in a simplified form, by straight lines as shown in FIG. 1. In some examples, the metal layers are patterned to define electrical routing or conductive traces that are electrically coupled between different metal layers by conductive (e.g., metal) vias extending through intervening dielectric layers.

Using glass as a starting core material (e.g., the glass core 132 of FIG. 1) has a mechanical benefit (e.g., reduced warpage, smaller thickness variation), an electrical benefit, and a design flexibility benefit (e.g., tighter through-hole pitch, finer core routing) over using traditional organic core materials (e.g., epoxy-based prepreg). For example, the glass core 132 can support multi-chip packaging (e.g., embedded multi-die interconnect bridge (EMIB), 2.5D/3D heterogeneous integration, hyper chip stacking (silicon (Si) interposers), etc.), reduced first level interconnect (FLI) bump pitches (e.g., less than 30 micrometer (μm)), reduced fine line spacing (FLS) (e.g., 2/2 μm), higher density interconnects, higher input/output (I/O) density patterning, increasing form factors, and decreasing package thicknesses over the traditional organic core materials. To further facilitate these advantages, the glass core 132 can include through-glass vias (TGVs) (e.g., copper-plated vias) extending through the glass core 132 to electrically couple the build-up region 134 to the build-up region 136. While examples described herein are described with reference to the glass core 132, it should be appreciated that teachings of this disclosure are not limited thereto. For example, the teachings of this disclosure are also applicable to organic cores.

A common type of failure of known glass cores is a seware failure. Seware failures result in the separation of a glass core along a crack that propagates from an edge of the glass core along its length and width between two or more of the outer surfaces (e.g., the upper and lower surfaces, the front and back surfaces, etc.) of the glass core. That is, seware failures are characterized by a glass core splitting into two separate sheets of glass along a line extending generally parallel to the main plane of the glass core.

One factor that contributes to seware failure is stress concentrations in cavities of the glass core, such as the cavities that receive power delivery components. Power delivery components, such as inductors (e.g., coaxial metal inductor loops (CMILs)), through glass vias (TGVs), and plated through holes (PTHs), are often positioned in closely packed cavities in prior glass cores due to routing and spatial constraints. The formation of densely packed cavities in prior glass cores creates a thin webbing between such densely packed cavities. These cavities and the webbing associated therewith can lead to large stress concentrations in the thin glass walls of the webbing of the cavities caused by loading the substrate. Particularly, the corners and/or the thin walls of the webbing of the glass cores can cause large stress concentrations, which can lead to the cracking and failure of the glass core.

Examples disclosed herein overcome some or all of the above-noted problems and include glass cores with embedded power delivery components. An example glass core disclosed herein includes a large cavity including a dielectric filler that supports a plurality of power delivery components. Another example glass core disclosed herein includes a recessed portion that includes embedded power delivery components. In some such example glass cores disclosed herein, the reduced thickness of the power delivery portion of the glass core reduces the stress concentrations in the recessed portion. Some example glass cores disclosed herein include six coaxial metal inductor loop (CMIL) clusters, which are offset to enable the placement of PTHs between the CMIL clusters. Some example glass cores disclosed herein include cavities with filleted, beveled, and/or chamfered edges to reduce stress concentrations along the edges. Examples disclosed herein substantially reduce the number of failure points associated with the embedded power delivery components in glass cores when compared to prior glass core designs.

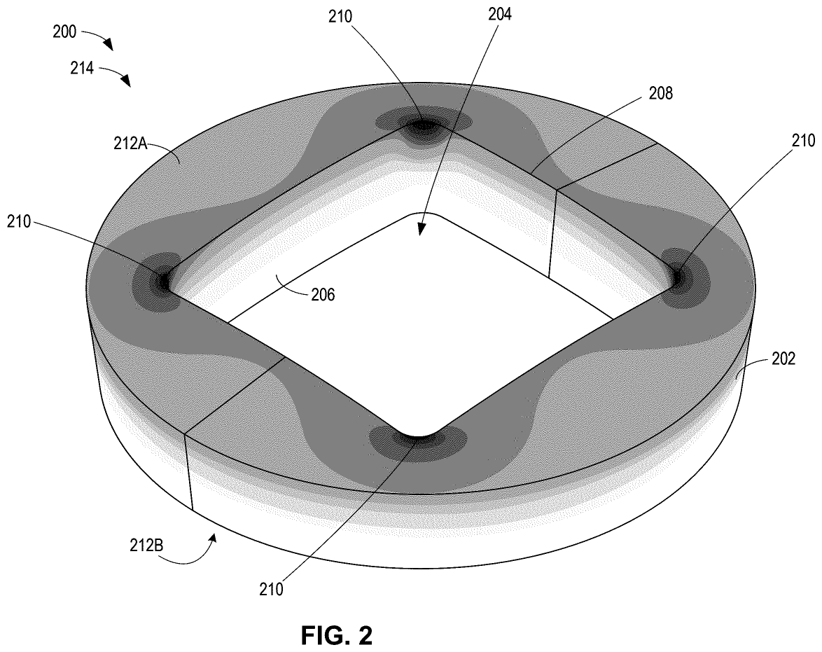

FIG. 2 illustrates a perspective view of an example first glass core 200 that can be used with the example IC package 100 of FIG. 1. More particularly, in some examples, the first glass core 200 of FIG. 2 can be used to implement the example glass core 132 of FIG. 1. In the illustrated example of FIG. 2, the first glass core 200 includes an example body 202 and an example cavity 204. In the illustrated example of FIG. 2, the cavity 204 is defined by an example interior wall 206 and includes an example edge 208 having example corners 210. In the illustrated example of FIG. 2, the body 202 has an example top surface 212A and an example bottom surface 212B. In the illustrated example of FIG. 2, the top surface 212A is opposite to the bottom surface 212B (e.g., the surfaces 212A, 212B are opposing surfaces, etc.). In the illustrated example of FIG. 2, the surfaces 212A, 212B are the outer surface of the body 202 (e.g., the top surface 212A is a first outer surface, the bottom surface 212B is a second outer surface, etc.).

The body 202 is the structural component of the glass core 200. That is, the body 202 mechanically supports components mounted on the glass core 200 (e.g., the dies 108, 110 of FIG. 1, the build-up regions 134, 136 of FIG. 1, etc.). In some examples, the body 202 is a glass layer of a substrate of a package substrate (e.g., the IC package 100, etc.). The body 202 includes (e.g., contains, is composed of, etc.) glass (e.g., one or more of the glass compositions discussed in conjunction with the glass core 132 of FIG. 1, etc.). In other examples, the body 202 can be composed of a different material. It should be appreciated that only a portion of the body 202 is illustrated in FIG. 2 and that the body 202 can extend planarly along the surfaces 212A, 212B. In some such examples, the body 202 can include additional cavities similar to the cavity 204, which can include additional power delivery components. As used herein, the body 202 is also referred to as a structural portion of the glass core 200.

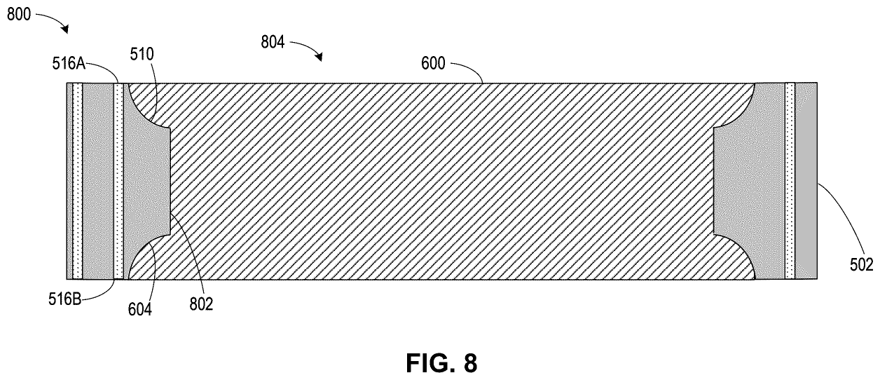

The cavity 204 is a through hole that extends through the body 202. In the illustrated example of FIG. 2, the cavity 204 has a generally square-shaped cross section (e.g., the edge 208 includes four sides, etc.) with rounded corners (e.g., the corners 210 are rounded, etc.). In other examples, the cavity 204 can have a differently shaped cross-section (e.g., a different polygon, a circle, an oval, etc.). Further, the radius of curvature of the corners 210 can be larger or smaller than what is shown in the illustrated example. In the illustrated example of FIG. 2, the cavity 204 has a constant cross-sectional shape and size between the top surface 212A and the bottom surface 212B. In other examples, the cavity 204 has a variable cross-section along the thickness of the body 202. For example, the cavity 204 can be cone-shaped and/or tapered (e.g., wider at the top surface 212A than the bottom surface 212B, wider at the bottom surface 212B than the top surface 212A, etc.), hourglass-shaped (e.g., wider at the opposing surfaces 212A, 212B than a mid-point therebetween, etc.) and/or have any other suitable cross-sectional profile between the surfaces 212A, 212B. In the illustrated example of FIG. 2, the edge 208 is defined by the interior wall 206 and the top surface 212A. In some examples, the edge 208 can be beveled, chamfered, and/or filleted. In some examples, edge between the interior wall 206 and the bottom surface 212B is also beveled, chamfered, and/or filleted. An example glass core with filleted edges is described below in conjunction with FIG. 8.

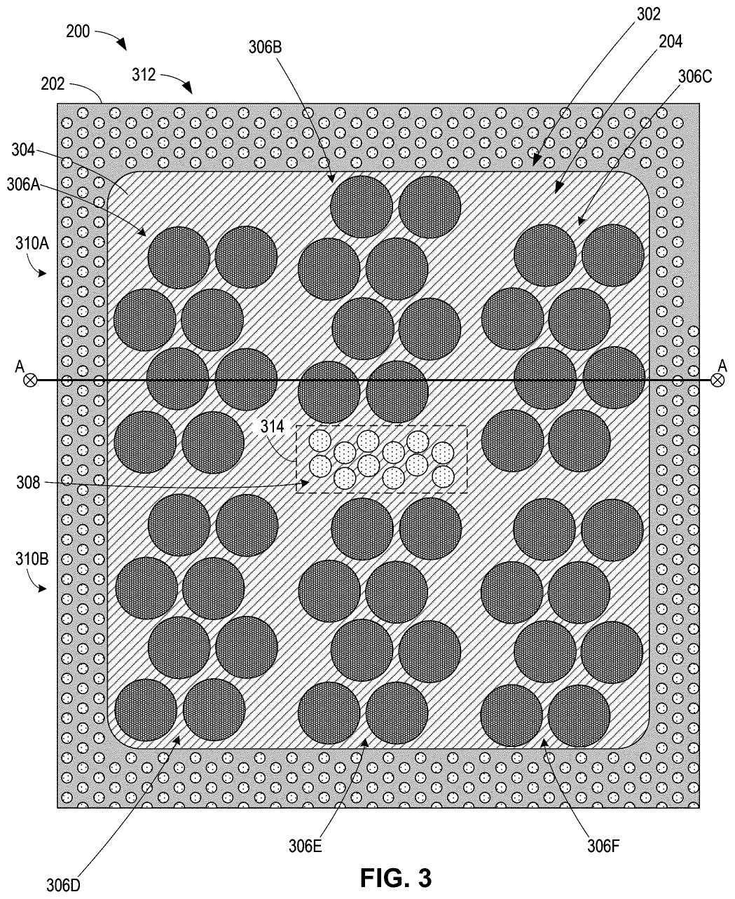

The cavity 204 can support (e.g., house, contain, receive, etc.) a power delivery portion of the glass core 200. An example power delivery portion that can be contained within the cavity 204 is described below in conjunction with FIG. 3. In some examples, the interior wall 206 of the cavity 204 is an interface (e.g., a mechanical interface, a material interface, etc.) between the body 202 and the power delivery portion disposed within the cavity 204.

In the illustrated example of FIG. 2, an example stress concentration map 214 is overlayed on the first glass core 200. The stress concentration map 214 is reflective of the stress experienced by the body 202 when the glass core 200 is subject to biaxial bending. That is, in the illustrated example of FIG. 2, the stress concentration map 214 corresponds to the stress that would be experienced by the glass core 200 in an IC package (e.g., the IC package of FIG. 1, etc.). In the illustrated example of FIG. 2, darker portions on the stress concentration map 214 correspond to areas of the body 202 that are experiencing greater stress and lighter portions on the stress concentration map 214 correspond to areas of the body 202 that are experiencing comparatively less stress. In the illustrated example of FIG. 2, the corners 210 are the only portion of the body 202 that are subjected to high-stress concentrations. In some examples, the corners 210 can be further rounded to reduce the stress concentration(s) experienced thereby (e.g., the radius of the corners 210 can be increased to reduce the stress experienced thereby, etc.).

FIG. 3 is a top view of the first glass core 200 of FIG. 2 including an example power delivery portion 302. In the illustrated example of FIG. 3, the power delivery portion 302 is disposed in the cavity 204 of the body 202 of FIG. 2. In the illustrated example of FIG. 3, the power delivery portion 302 includes an example dielectric filler 304, an example first CMIL cluster 306A, an example second CMIL cluster 306B, an example third CMIL cluster 306C, an example fourth CMIL cluster 306D, an example fifth CMIL cluster 306E, an example sixth CMIL cluster 306F, and an example PTH cluster 308. In the illustrated example of FIG. 3, the CMIL clusters 306A, 306B, 306C are arranged in an example first row 310A and the CMIL clusters 306D, 306E, 306F are arranged in an example second row 310B. In the illustrated example of FIG. 3, the body 202 includes a plurality of TGVs 312.

The example dielectric filler 304 is a non-conductive material that structurally supports and surrounds the CMIL clusters 306A, 306B, 306C, 306D, 306E, 306F and the PTH cluster 308. In the illustrated example of FIG. 3, the dielectric filler 304 is positioned in the cavity 204 of FIG. 2. In some examples, the dielectric filler 304 is an organic epoxy (e.g., an organic resin, an organic mold material, etc.). In other examples, the dielectric filler 304 can be composed of any other suitable kind of non-conductive material (e.g., a plastic, a ceramic, a build-up film, etc.).

The CMIL clusters 306A, 306B, 306C, 306D, 306E, 306F are clusters of power delivery interconnects that extend through the glass core 200 between the top surface 212A and the bottom surface 212B. The interconnects of the CMIL clusters 306A, 306B, 306C, 306D, 306E, 306F enhance power delivery through the glass core 200. In the illustrated example of FIG. 3, the interconnects of the CMIL clusters 306A, 306B, 306C, 306D, 306E, 306F are disposed in the dielectric filler 304 of the power delivery portion 302. That is, the CMIL clusters 306A, 306B, 306C, 306D, 306E, 306F extend through the dielectric filler 304. In the illustrated example of FIG. 3, the CMIL clusters 306A, 306B, 306C, 306D, 306E, 306F extend continuously around and between each of the CMIL clusters 306A, 306B, 306C, 306D, 306E, 306F. That is, the dielectric material 304 is deposited as a single integral component around each of the CMIL clusters 306A, 306B, 306C, 306D, 306E, 306F (e.g., the dielectric material 304 extends continuously from around the first CMIL cluster 306A to around the second CMIL cluster 306B, etc.). In the illustrated example of FIG. 3, each of the CMIL clusters 306A, 306B, 306C, 306D, 306E, 306F is spaced apart from other ones of the CMIL clusters 306A, 306B, 306C, 306D, 306E, 306F.

In the illustrated example of FIG. 3, each of the CMIL clusters 306A, 306B, 306C, 306D, 306E, 306F include eight CMILs. In other examples, some or all of the CMIL clusters 306A, 306B, 306C, 306D, 306E, 306F can include a different number of CMILs (e.g., one CMIL, two CMIL, etc.). In the illustrated example of FIG. 3, the interconnects of the CMIL clusters 306A, 306B, 306C, 306D, 306E, 306F are arranged in four rows of two interconnects that are alternatively offset. In other examples, some or all of the CMIL clusters 306A, 306B, 306C, 306D, 306E, 306F can have different arrangements. In the illustrated example of FIG. 3, the CMIL clusters 306A, 306B, 306C, 306D, 306E, 306F are arranged in two rows (e.g., the rows 310A, 310B, etc.). In other examples, the CMIL clusters 306A, 306B, 306C, 306E, 306F are in a different arrangement (e.g., one row, three rows, five rows, etc.). In the illustrated example of FIG. 3, the second CMIL cluster 306B is offset from the first CMIL cluster 306A and the third CMIL cluster 306C, such that an example offset gap 314 is formed in power delivery portion 302. That is, the lateral offset of the second CMIL cluster 306B from the first CMIL cluster 306A and the third CMIL cluster 306C in the first row 310A creates the offset gap 314 in the center of the power delivery portion 302. In the illustrated example of FIG. 3, each of the inductors of each of the CMIL clusters 306A, 306B, 306C, 306D, 306E, 306F is closer to adjacent inductors in the same CMIL cluster than to the closest inductor in other ones of the CMIL clusters 306A, 306B, 306C, 306D, 306E, 306F (e.g., each inductor in the first CMIL cluster 306A is spaced a first distance to adjacent inductors in the first CMIL cluster 306A and is spaced a second distance to the closest inductor in each of the other CMIL clusters 306B, 306C, 306D, 306E, 306F where the second distance is greater than the first distance, etc.).

In the illustrated example of FIG. 3, the PTH cluster 308 is disposed in the offset gap 314. That is, the PTH cluster 308 is disposed at the center of the power delivery portion 302 (e.g., the center of the dielectric filler 304, etc.). Like the CMIL clusters 306A, 306B, 306C, 306D, 306E, 306F, the PTH cluster 308 enhances power delivery through the glass core 200. In the illustrated example of FIG. 3, the PTH cluster 308 is disposed in the dielectric filler 304 of the power delivery portion 302. In the illustrated example of FIG. 3, the PTH cluster 308 includes twelve interconnects. In other examples, the PTH cluster 308 can include any other suitable number of interconnects (e.g., one interconnect, five interconnects, ten interconnects, twenty interconnects, etc.) In the illustrated example of FIG. 3, the interconnects of the PTH cluster 308 are disposed in six alternately offset columns of two interconnects. In other examples, the interconnects of the PTH cluster 308 can have any other suitable arrangement, such as a different number of columns (e.g., one column, two columns, ten columns, etc.) and/or a different number of PTHs within a given column (e.g., one PTH, three PTHs, five PTHs, etc.). In other examples, the offset gap 314 is absent and the CMIL clusters 306A, 306B, 306C are laterally aligned in the first row 310A (e.g., similar to the arrangement of the CMIL clusters 306D, 306E, 306F in the second row 310B, etc.). In some such examples, the PTH cluster 308 is absent and/or positioned at another location in the power delivery portion 302 (e.g., near the edge 208 of FIG. 2, laterally between the first CMIL cluster 306A and the fourth CMIL cluster 306D, laterally between the third CMIL cluster 306C and the sixth CMIL cluster 306F, etc.).

In the illustrated example of FIG. 3, the power delivery portion 302 includes the CMIL clusters 306A, 306B, 306C, 306D, 306E, 306F and the PTH cluster 308. Additionally or alternatively, the power delivery portion 302 can include other power delivery components disclosed herein. For example, the power delivery portion 302 can include one or more capacitors (e.g., deep trench capacitors (DTCs), thin-film capacitors, etc.), one or more other interconnects (e.g., a silicon-based interconnect bridge, an interconnect die, an embedded interconnect bridge (EMIB), etc.), and/or any other components that can be embedded within the glass core 200.

The TGVs 312 are through glass vias that are composed of electrically conductive material (e.g., copper, silver, etc.) that extend through the body 202. The TGVs 312 enable electric signals and/or power to be routed through the body 202 (e.g., between the surfaces 212A, 212B, etc.). In the illustrated example of FIG. 3, the TGVs 312 are arranged in an offset grid. That is, in the illustrated example of FIG. 3, the TGVs 312 are arranged in offset rows and columns. In the other examples, the TGVs 312 are arranged in other pattern(s). In some examples, the TGVs 312 are absent.

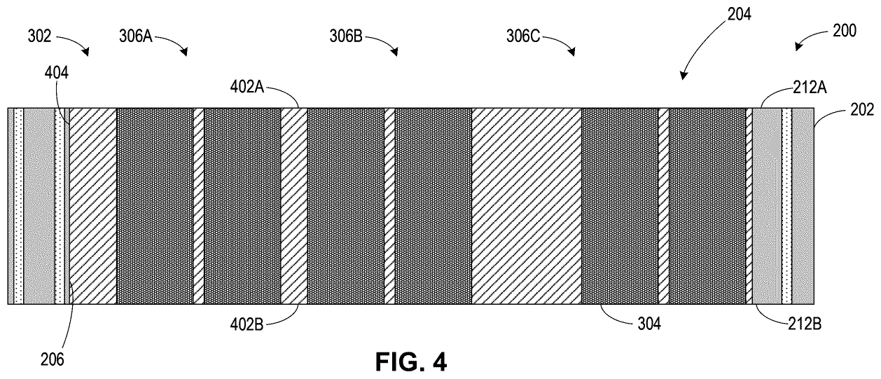

FIG. 4 is a cross-sectional side view of the example first glass core 200 of FIG. 2 including the power delivery portion 302 of FIG. 3 taken along the A-A line of FIG. 3. In the illustrated example of FIG. 4, the power delivery portion 302 includes an example top surface 402A, an example bottom surface 402B, and an example outer wall 404. In the illustrated example of FIG. 4, the top surface 402A is flush with the top surface 212A of the body 202 and the bottom surface 402B is flush with the bottom surface 212B of the body 202. In other examples, either or both of the surfaces 402A, 402B of the power delivery portion 302 are recessed and/or protruding from the surfaces 212A, 212B of the body 202, respectively. In some examples, the surfaces 402A, 402B and/or the surfaces 212A, 212B are etched, polished and/or planarized such that the surfaces 402A, 402B and/or the surfaces 212A, 212B are flush.

In the illustrated example of FIG. 4, the outer wall 404 of the power delivery portion 302 and dielectric filler 304 (e.g., an external wall of the power delivery portion 302, etc.) is adjacent to the interior wall 206 of the cavity 204 of the glass core 200 (e.g., an internal surface of the cavity 204 of the glass core 200, etc.). In the illustrated example of FIG. 4, the outer wall 404 and the interior wall 206 are straight (e.g., straight walled, etc.). In the illustrated example of FIG. 4, the outer wall 404 is in contact with (e.g., abuts, etc.) the interior wall 206 along the depth of the cavity 204. In other examples, an adhesive and/or an adhesion promoter is disposed between the outer wall 404 and the interior wall 206.

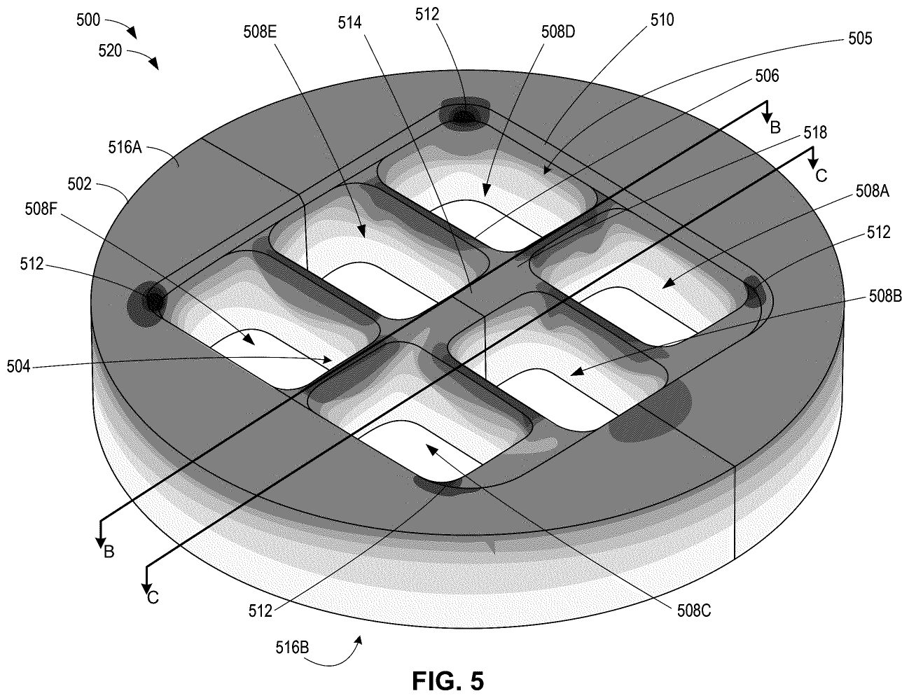

FIG. 5 illustrates a perspective view of an example second glass core 500 that can be used with the example IC package of FIG. 1. More particularly, in some examples, the second glass core 500 of FIG. 2 can be used to implement the example glass core 132 of FIG. 1. The second glass core 500 is similar to the first glass core 200 of FIGS. 2-4, except as noted otherwise. In the illustrated example of FIG. 5, the second glass core 500 includes an example body 502, an example first recessed portion 504, an example first opening 505, an example webbing 506, an example first cavity 508A, an example second cavity 508B, an example third cavity 508C, an example fourth cavity 508D, an example fifth cavity 508E, and an example sixth cavity 508F. In the illustrated example of FIG. 5, the body 502 includes an example edge 510 having example corners 512. The body 502 is the structural component of the second glass core 500. The body 502 is similar to the body 202 of FIG. 2, except as noted otherwise. As used herein, the body 502 is also referred to as a structural portion of the second glass core 500.

In the illustrated example of FIG. 5, the first recessed portion 504 includes an example central platform 514. In the illustrated example of FIG. 5, the body 502 has an example top surface 516A and an example bottom surface 516B. In the illustrated example of FIG. 5, the surfaces 516A, 516B are the outer surface of the body 502 (e.g., the top surface 516A is a first outer surface, the bottom surface 516B is a second outer surface, etc.). In the illustrated example of FIG. 2, the top surface 516A is opposite to the bottom surface 516B (e.g., the surfaces 516A, 516B are opposing surfaces, etc.). In the illustrated example of FIG. 5, the first recessed portion 504 includes an example first inner surface 518 (e.g., a recessed or inset surface). In the illustrated example of FIG. 5, an example stress concentration map 520 is overlayed on the second glass core 500.

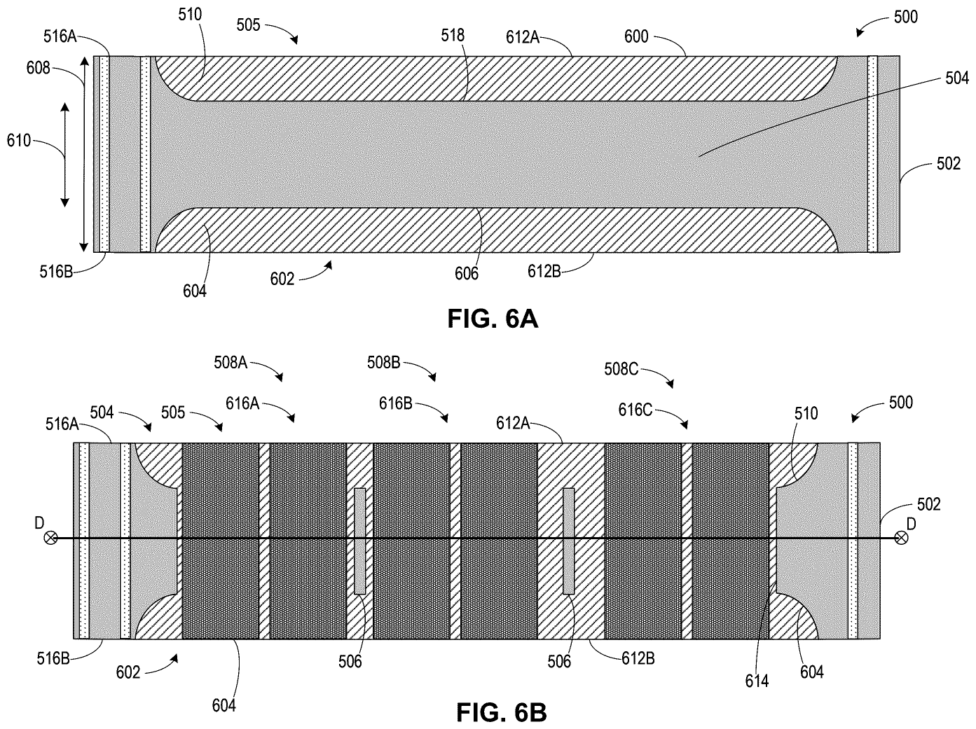

The first recessed portion 504 is a portion of the second glass core 500 that is enclosed by (e.g., spaced inward of, etc.) the body 502. That is, the first recessed portion 504 and the first inner surface 518 are inset from the body 502 and the top surface 516A by the first opening 505. In the illustrated example of FIG. 5, the first recessed portion 504 includes the webbing 506 and the central platform 514. In the illustrated example of FIG. 5, the webbing 506 includes a plurality of glass walls disposed between the cavities 508A, 508B, 508C, 508D, 508E, 508F (e.g., the webbing 506 includes a first glass wall separating the first cavity 508A and the second cavity 508B, the webbing 506 includes a second glass wall separating the first cavity 508A and the fourth cavity 508D, etc.). In the illustrated example of FIG. 5, the webbing 506 and the central platform 514 are integral with the body 502. In some such examples, the first opening 505 can be formed during the initial formation of the second glass core 500 (e.g., the spin-coating of the second glass core 500, the molding of the second glass core 500, the casting of the second glass core 500, etc.). Additionally or alternatively, the first opening 505 can be formed after the initial formation of the second glass core 500 (e.g., via routing, laser induced etching, etc.). The first recessed portion 504 and the first opening 505 are described below in conjunction with FIGS. 6A and 6B. In some examples, the bottom surface 516B of the body 202 includes an opening similar to the first opening 505. In some examples, the first recessed portion 504 is the power delivery portion of the second glass core 500.

The cavities 508A, 508B, 508C, 508D, 508E, 508F are through holes that extend through the body 502. In some examples, each of the cavities 508A, 508B, 508C, 508D, 508E, 508F can house (e.g., contain, surround, etc.) one or more corresponding power delivery component(s) (e.g., a CMIL cluster, etc.). In the illustrated example of FIG. 5, the cavities 508A, 508B, 508C, 508D, 508E, 508F have a generally rectangular shaped cross section with rounded corners (e.g., the corners of the cavities 508A, 508B, 508C, 508D, 508E, 508F are rounded, etc.). In other examples, some or all of the cavities 508A, 508B, 508C, 508D, 508E, 508F can have a differently shaped cross-section (e.g., a square, a different polygon, a circle, an oval, etc.). Further, the radius of curvature of the corners 210 can be larger or smaller than what is shown in the illustrated example. In the illustrated example of FIG. 5, each of the cavities 508A, 508B, 508C, 508D, 508E, 508F have a constant cross-sectional shape and size through the recessed portions 504. In other examples, some or all of the cavities 508A, 508B, 508C, 508D, 508E, 508F have a variable cross-section along the thickness of the body 502. For example, some or all of the cavities 508A, 508B, 508C, 508D, 508E, 508F can be cone-shaped and/or tapered, hourglass-shaped, and/or have any other suitable cross-sectional area profile.

In some examples, the first opening 505 and/or the cavities 508A, 508B, 508C, 508D, 508E, 508F are filled with a dielectric filler similar to the dielectric filler. In some such examples, the power delivery components (e.g., TGVs, PTHs, CMILs, etc.) can be disposed within the dielectric filler and the first recessed portion 504. Cross-sectional views of the glass core 500 including a dielectric filler similar to the dielectric filler 304 of FIG. 4 are described below in conjunction with FIGS. 6A and 6B. It should be appreciated that a top view of the second glass core 500 is substantially similar to the top view of the glass core 200 of FIG. 2 depicted in FIG. 3.

The edge 510 (e.g., the straight portions of the edge 510 and the corners 512, etc.) is a transition surface that extends around the first recessed portion 504. In the illustrated example of FIG. 5, the edge 510 is defined between the first recessed portion 504 and the top surface 516A. In the illustrated example of FIG. 5, the edge 510 is filleted (e.g., rounded, curved, etc.). That is, in the illustrated example of FIG. 5, the edge 510 is a curved surface (e.g., a curved transition surface, etc.) between the first recessed portion 504 and the body 502. In other examples, the edge 510 can be beveled and/or chamfered. In some examples, the edge 510 is an interface (e.g., a mechanical interface, a material interface, etc.) between the body 502 and a power delivery portion of the second glass core 500 including the first recessed portion 504. The edge 510 is described below in additional detail in conjunction with FIG. 6A.

In the illustrated example of FIG. 5, the central platform 514 of the second glass core 500 is disposed between the cavities 508A, 508B, 508C, 508D, 508E, 508F. Similar to the CMIL clusters 306A, 306B, 306C, 306D, 306E, 306F of FIG. 3, the cavities 508A, 508B, 508C, 508D, 508E, 508F are distributed to facilitate the presence of the central platform 514 in the center of the first recessed portion 504 (e.g., the central platform 514 corresponds to the offset gap 314 of FIG. 3, etc.). That is, the second cavity 508B is offset from the first cavity 508A and the third cavity 508C (e.g., the spacing between the second cavity 508B and the fifth cavity 508E is greater than the spacing between the first cavity 508A and the fourth cavity 508D and the spacing between the third cavity 508C and the sixth cavity 508F, etc.). In some examples, one or more power delivery components (e.g., through glass vias, etc.) are formed positioned in the central platform 514. In the illustrated example of FIG. 5, the central platform 514 is flush with the first inner surface 518 of the first recessed portion 504. In other examples, the central platform 514 is flush with the top surface 516A.

In the illustrated example of FIG. 5, the stress concentration map 520 is reflective of the stress experienced by the body 502 when the second glass core 500 is subject to biaxial bending (e.g., the same loading associated with the stress concentration map 214 of FIG. 2, etc.). In the illustrated example of FIG. 5, darker portions on the stress concentration map 520 correspond to areas of the body 502 experiencing greater stress and lighter portions on the stress concentration map 520 correspond to areas of the body 502 that experience comparatively less stress. In the illustrated example of FIG. 5, the corners 512 and the thin walls of the webbing 506 are subject to stress concentrations. In some examples, the first recessed portion 504 and the easing of the edge 510 (e.g., the beveling of the edge 510, the filleting of the edge 510, the chamfering of the edge 510, etc.) reduces the relative portion of stress transferred through the core (e.g., compared to prior cores without the first recessed portion 504, etc.) and increases the relative portion of the stress transferred through the body 502, which reduces the likelihood of a failure (e.g., a seware failure, etc.) occurring at the webbing 506 or the corners 512.

FIGS. 6A and 6B are cross-sectional side views of the example second glass core 500 of FIG. 5 taken along the B-B line and the C-C line, respectively, of FIG. 5. In the illustrated example of FIGS. 6A and 6B, the second glass core 500 includes an example dielectric filler 600. The dielectric filler 600 is similar to the dielectric filler 304 of FIG. 3, except as noted otherwise. In the illustrated example of FIGS. 6A and 6B, the second glass core 500 includes the first recessed portion 504 of FIG. 5, the first opening 505 of FIG. 5, and an example second opening 602, which is similar to the first opening 505, except that the second opening 602 is formed in the bottom surface 516B. In the illustrated example of FIGS. 6A and 6B, the dielectric filler 600 is disposed in the openings 505, 602 and the cavities 508A, 508B, 508C, 508D, 508E, 508F. In the illustrated example of FIG. 6A, the dielectric filler 600 is vertically aligned with the recessed portion 504. That is, the dielectric filler 600 is aligned with the recessed portion 504 in a direction normal (e.g., orthogonal, etc.) to the surfaces 212A, 212B.

In the illustrated example of FIGS. 6A and 6B, the second glass core 500 includes the first edge 510 of FIG. 5 and an example second edge 604, which is similar to the first edge 510, except that the second edge 604 is between the bottom surface 516B and an example second inner surface 606 of the first recessed portion 504. In the illustrated example of FIG. 5, the second opening 602 and the second edge 604 have the same size and shape as the first opening 505 and the first edge 510, respectively. In other examples, the second opening 602 and the second edge 604 can have different sizes and/or shapes as the first opening 505 and the first edge 510, respectively. In some examples, the first opening 505 and/or the second opening 602 are absent (e.g., the first inner surface 518 is flush with the top surface 516A, the second inner surface 606 is flush with the bottom surface 516B, etc.).

In the illustrated example of FIG. 6A, the body 502 of the second glass core 500 has an example first thickness 608 and the first recessed portion 504 has an example second thickness 610. In the illustrated example of FIG. 6A, the first thickness 608 is approximately 60% of the length of the second thickness 610. In some examples, the first thickness 608 can be between 10% and 90% of the length of the first thickness 608. In some examples, the thickness 608 is 200 microns (e.g., each of the openings 505, 602 has a depth of 100 microns, etc.). In other examples, the first thickness 608 can be any other suitable size.

In the illustrated example of FIGS. 6A and 6B, the dielectric filler 600 in the first recessed portion 504 includes an example top surface 612A, an example bottom surface 612B, and an example outer wall 614. In the illustrated example of FIGS. 6A and 6B, the dielectric filer 600 extends around an upper end of the glass walls of the webbing 506 (e.g., the end of the glass walls proximate to the first opening 505, etc.) and a lower end of the glass walls of the webbing 506 (e.g., the end of the glass walls proximate to the second opening 602, etc.). That is, in the illustrated example of FIGS. 6A and 6B, the dielectric filler 600 is disposed in the openings 505, 602 and above and between the glass walls of the webbing 506.

In the illustrated example of FIGS. 6A and 6B, the top surface 612A of the dielectric filler 600 is flush with top surface 516A and the bottom surface 612B of the dielectric filler 600 is flush with the bottom surface 516B. In some examples, the surfaces 516A, 516B and/or the surfaces 612A, 612B are etched, polished, and/or planarized such that the surfaces 516A, 516B, and/or the surfaces 612A, 612B are flush. In the illustrated example of FIG. 6B, the outer wall 614 of the power delivery portion 302 and dielectric filler 304 is adjacent to the edges 510, 604 of the second glass core 500. In the illustrated example of FIG. 6B, the outer wall 614 is in contact with (e.g., abuts, etc.) the edges 510, 604. In other examples, an adhesive and/or an adhesion promoter can be disposed between the outer wall 614 and the edges 510, 604.

In the illustrated example of FIG. 6B, the second glass core 500 includes an example first CMIL cluster 616A, an example second CMIL cluster 616B, and an example third CMIL cluster 616C, which are disposed in the example first cavity 508A, an example second cavity 508B, and an example third cavity 508C, respectively. The CMIL clusters 616A, 616B, 616C are similar to the CMIL clusters 306A, 306B, 306C, 306D, 306E, 306F of FIG. 3, except as noted otherwise. In the illustrated example of FIG. 6B, the CMIL clusters 616A, 616B, 616C extend through the dielectric filler 600 in the openings 505, 602 and the cavities 508A, 508B, 508C. In the illustrated example of FIG. 6B, webs of the webbing 506 are disposed between the first CMIL cluster 616A and the second CMIL cluster 616B, and between the second CMIL cluster 616B and the third CMIL cluster 616C.

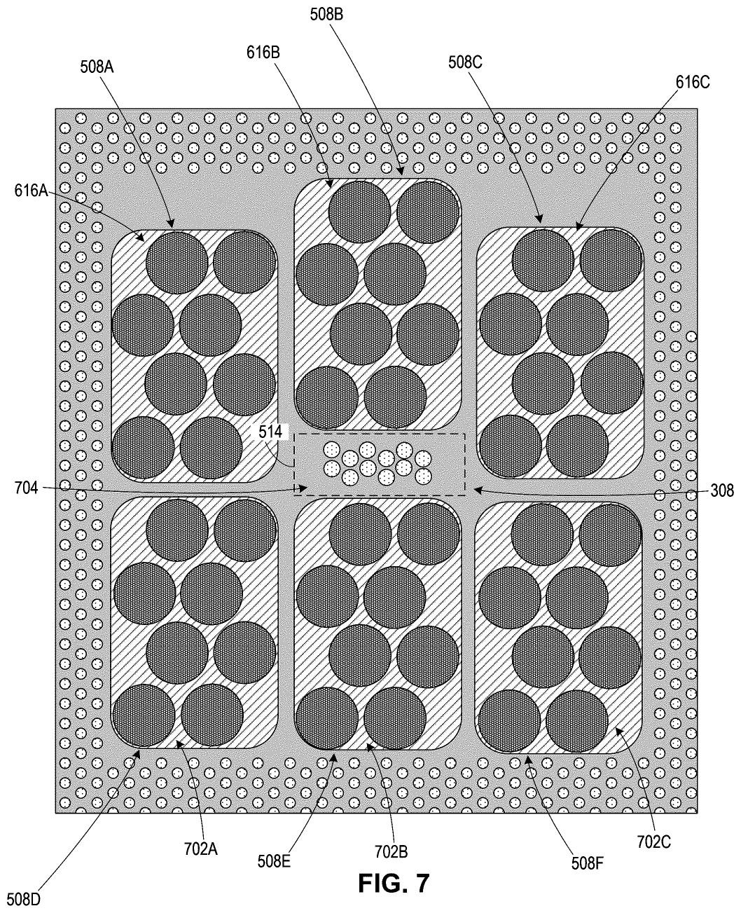

FIG. 7 is a cross-sectional top view of the example second glass core 500 of FIGS. 5, 6A, and 6B taken along the D-D line of FIG. 6B. In the illustrated example of FIG. 7, the second glass core 500 includes the first CMIL cluster 616A of FIG. 6, the second CMIL cluster 616B, the third CMIL cluster 616C, an example fourth CMIL cluster 702A, an example fifth CMIL cluster 702B, an example sixth CMIL cluster 702C, and an example TGV cluster 704. In the illustrated example of FIG. 7, the body 502 includes the plurality of TGVs 312 of FIG. 3. In other examples, some or all of the plurality of TGVs 312 are absent.

The CMIL clusters 702A, 702B, 702C are similar to the CMIL clusters 616A, 616B, 616C of FIG. 6B, except as noted otherwise. In the illustrated example of FIG. 7, the CMIL clusters 616A, 616B, 616C, 702A, 702B, 702C have the same external and internal arrangements as the CMIL clusters 306A, 306B, 306C, 306D, 306E, 306F of FIG. 3. In other examples, some or all of the CMIL clusters 616A, 616B, 616C, 702A, 702B, 702C can have different internal arrangements and/or the CMIL clusters 616A, 616B, 616C, 702A, 702B, 702C can have a different external arrangement.

In the illustrated examples of FIGS. 6B and 7, the CMIL clusters 616A, 616B, 616C, 702A, 702B, 702C extend through the dielectric filler 600. In the illustrated example of FIGS. 6B and 7, the CMIL clusters 616A, 616B, 616C, 702A, 702B, 702C extend continuously around and between each of the CMIL clusters 616A, 616B, 616C, 702A, 702B, 702C and the walls of the webbing 506. That is, the dielectric material 600 is deposited as a single integral component around each of the CMIL clusters 616A, 616B, 616C, 702A, 702B, 702C (e.g., the dielectric material 600 extends continuously from around the first CMIL cluster 616A to around the second CMIL cluster 616B, etc.) and the walls of the webbing 506. In the illustrated example of FIG. 3, each of the CMIL clusters 616A, 616B, 616C, 702A, 702B, 702C is spaced apart from other ones of the CMIL clusters 616A, 616B, 616C, 702A, 702B, 702C.

In the illustrated example of FIG. 7, the TGV cluster 704 are disposed in the central platform 514. The TGV cluster 704 enables and enhances power delivery through the second glass core 500. In the illustrated example of FIG. 7, the TGV cluster 704 are arranged in a manner similar to the arrangement of the PTH cluster 308 of FIG. 3. In other examples, the TGV cluster 704 can have any other suitable arrangement. As discussed above, it is possible to make smaller PTHs at a finer pitch through a glass core than it is through a traditional organic epoxy-based core. Accordingly, the example TGV cluster 704 of FIG. 7 is smaller than the example PTH cluster 308 of FIG. 3.

FIG. 8 is a cross-sectional side view of an example third glass core 800 implemented in accordance with teachings of this disclosure. In the illustrated example of FIG. 8, the third glass core 800 includes the body 502 of FIG. 5 and the dielectric filler 600 of FIG. 6. In the illustrated example of FIG. 8, the third glass core 800 includes the surfaces 516A, 516B of FIG. 5 and edges 510, 604 of FIG. 6. The third glass core 800 is similar to the second glass core 500 of FIG. 5, except that the webbing 506 of FIG. 5 is absent. Instead, in the illustrated example of FIG. 8, the edges 510, 604 of the third glass core 800 extend between the surfaces 516A, 516B, respectively, and an example interior wall 802. That is, the third glass core 800 includes a through cavity 804, which is similar to the cavity 204 of FIG. 2. In the illustrated example of FIG. 8, the dielectric filler 600 abuts (e.g., is in contact with, etc.) the interior wall 802 along the depth of the cavity 804. In other examples, an adhesive and/or an adhesion promoter can be disposed between the interior wall 802 and the dielectric filler 600. In other words, the example third glass core 800 combines features of the example first glass core 200 of FIGS. 2-4 and the example second glass core 500 of FIGS. 5-7.

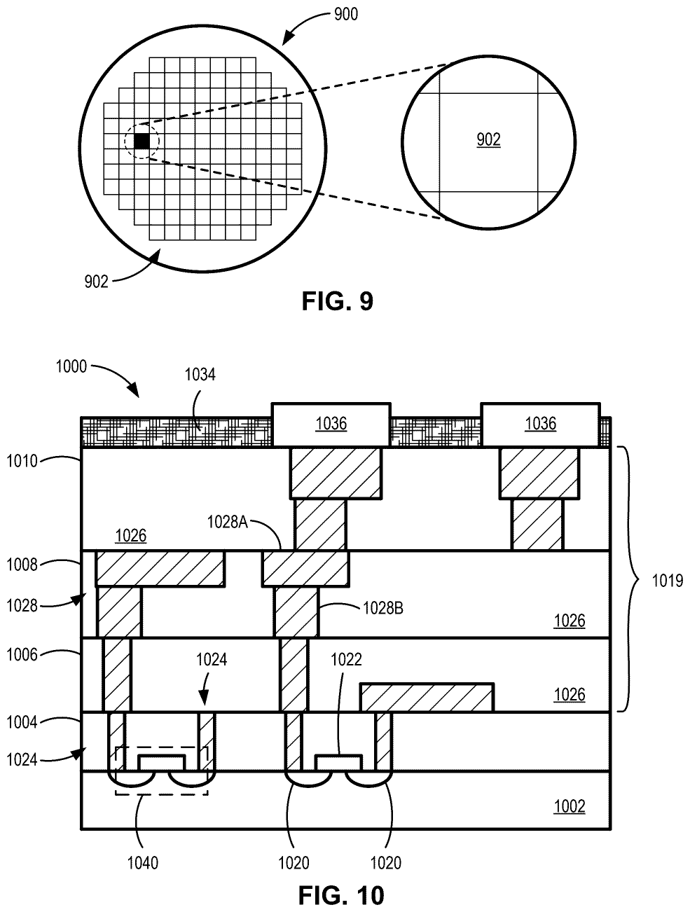

The example IC package 100 of FIG. 1 including the first glass core 200 of FIG. 2, the second glass core 500 of FIG. 5, the third glass core 800 of FIG. 8 may be included in any suitable electronic component. FIGS. 9-12 illustrate various examples of apparatus that may include or be included in the IC package 100 disclosed herein.

FIG. 9 is a top view of a wafer 900 and dies 902 that may be included in the IC package 100 of FIG. 1 (e.g., as any suitable ones of the dies 108, 110). The wafer 900 includes semiconductor material and one or more dies 902 having circuitry. Each of the dies 902 may be a repeating unit of a semiconductor product. After the fabrication of the semiconductor product is complete, the wafer 900 may undergo a singulation process in which the dies 902 are separated from one another to provide discrete “chips.” The die 902 includes one or more transistors (e.g., some of the transistors 1840 of FIG. 18, discussed below), supporting circuitry to route electrical signals to the transistors, passive components (e.g., traces, resistors, capacitors, inductors, and/or other circuitry), and/or any other components. In some examples, the die 902 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die (e.g., the die 902, etc.). For example, a memory array of multiple memory circuits may be formed on a same die (e.g., die 902 as programmable circuitry (e.g., the processor circuitry 2002 of FIG. 20) and/or other logic circuitry. Such memory may store information for use by the programmable circuitry. The example IC package 100 disclosed herein may be manufactured using a die-to-wafer assembly technique in which some dies are attached to a wafer 900 that includes others of the dies, and the wafer 900 is subsequently singulated.

FIG. 10 is a cross-sectional side view of an IC device 1000 that may be included in the example IC package 100 (e.g., in any one of the dies 108, 110). One or more of the IC devices 1000 may be included in one or more dies 902 (FIG. 9). The IC device 1000 may be formed on a die substrate 1002 (e.g., the wafer 900 of FIG. 9) and may be included in a die (e.g., the die 902 of FIG. 9). The die substrate 1002 may be a semiconductor substrate including semiconductor materials including, for example, n-type or p-type materials systems (or a combination of both). The die substrate 1002 may include, for example, a crystalline substrate formed using a bulk silicon or a silicon-on-insulator (SOI) substructure. In some examples, the die substrate 1002 may be formed using alternative materials, which may or may not be combined with silicon, which include but are not limited to germanium, indium antimonide, lead telluride, indium arsenide, indium phosphide, gallium arsenide, or gallium antimonide. Further materials classified as group II-VI, III-V, or IV may also be used to form the die substrate 1002. Although a few examples of materials from which the die substrate 1002 may be formed are described here, any material that may serve as a foundation for an IC device 1000 may be used. The die substrate 1002 may be part of a singulated die (e.g., the dies 902 of FIG. 9) or a wafer (e.g., the wafer 900 of FIG. 9).

The IC device 1000 may include one or more device layers 1004 disposed on and/or above the die substrate 1002. The device layer 1004 may include features of one or more transistors 1040 (e.g., metal oxide semiconductor field-effect transistors (MOSFETs)) formed on the die substrate 1002. The device layer 1004 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1040 may include a gate 1022 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 1040 along the source-channel-drain direction, the gate electrode may include a U-shaped structure that includes a bottom portion substantially parallel to the surface of the die substrate 1002 and two sidewall portions that are substantially perpendicular to the top surface of the die substrate 1002. In other examples, at least one of the metal layers that form the gate electrode may be a planar layer that is substantially parallel to the top surface of the die substrate 1002 and does not include sidewall portions substantially perpendicular to the top surface of the die substrate 1002. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of corresponding transistor(s) 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be carried out to fill the recesses with material that is used to fabricate the S/D regions 1020. In some implementations, the S/D regions 1020 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1020 may be formed using one or more alternate semiconductor materials such as germanium or a group III-V material or alloy. In further examples, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the IC device 1000.

The interconnect structures 1028 may be arranged within the interconnect layers 1006-1010 to route electrical signals according to a wide variety of designs (in particular, the arrangement is not limited to the particular configuration of interconnect structures 1028 depicted in FIG. 10). Although a particular number of interconnect layers 1006-1010 is depicted in FIG. 10, examples of the present disclosure include IC devices having more or fewer interconnect layers than depicted.

In some examples, the interconnect structures 1028 may include lines 1028A and/or vias 1028B filled with an electrically conductive material such as a metal. The lines 1028A may be arranged to route electrical signals in a direction of a plane that is substantially parallel with a surface of the die substrate 1002 upon which the device layer 1004 is formed. For example, the lines 1028A may route electrical signals in a direction in and/or out of the page from the perspective of FIG. 10. The vias 1028B may be arranged to route electrical signals in a direction of a plane that is substantially perpendicular to the surface of the die substrate 1002 upon which the device layer 1004 is formed. In some examples, the vias 1028B may electrically couple lines 1028A of different interconnect layers 1006-1010 together.

The interconnect layers 1006-1010 may include a dielectric material 1026 disposed between the interconnect structures 1028, as shown in FIG. 10. In some examples, the dielectric material 1026 disposed between the interconnect structures 1028 in different ones of the interconnect layers 1006-1010 may have different compositions; in other examples, the composition of the dielectric material 1026 between different interconnect layers 1006-1010 may be the same.

A first interconnect layer 1006 (referred to as Metal 1 or “M1”) may be formed directly on the device layer 1004. In some examples, the first interconnect layer 1006 may include lines 1028A and/or vias 1028B, as shown. The lines 1028A of the first interconnect layer 1006 may be coupled with contacts (e.g., the S/D contacts 1024) of the device layer 1004.

A second interconnect layer 1008 (referred to as Metal 2 or “M2”) may be formed directly on the first interconnect layer 1006. In some examples, the second interconnect layer 1008 may include vias 1028B to couple the lines 1028A of the second interconnect layer 1008 with the lines 1028A of the first interconnect layer 1006. Although the lines 1028A and the vias 1028B are structurally delineated with a line within each interconnect layer (e.g., within the second interconnect layer 1008) for the sake of clarity, the lines 1028A and the vias 1028B may be structurally and/or materially contiguous (e.g., simultaneously filled during a dual-damascene process) in some examples.

A third interconnect layer 1010 (referred to as Metal 3 or “M3”) (and additional interconnect layers, as desired) may be formed in succession on the second interconnect layer 1008 according to similar techniques and/or configurations described in connection with the second interconnect layer 1008 or the first interconnect layer 1006. In some examples, the interconnect layers that are “higher up” in the metallization stack 1019 in the IC device 1000 (i.e., further away from the device layer 1004) may be thicker.

The IC device 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to other external devices. For example, solder bonds may be formed on the one or more conductive contacts 1036 to mechanically and/or electrically couple a chip including the IC device 1000 with another component (e.g., a circuit board). The IC device 1000 may include additional or alternate structures to route the electrical signals from the interconnect layers 1006-1010; for example, the conductive contacts 1036 may include other analogous features (e.g., posts) that route the electrical signals to external components.

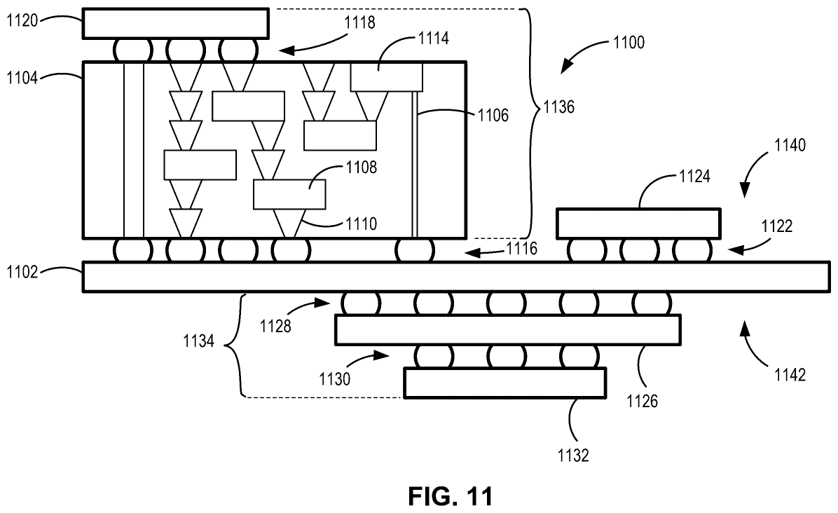

FIG. 11 is a cross-sectional side view of an IC device assembly 1100 that may include the IC package 100 disclosed herein. In some examples, the IC device assembly corresponds to the IC package 100. The IC device assembly 1100 includes a number of components disposed on a circuit board 1102 (which may be, for example, a motherboard). The IC device assembly 1100 includes components disposed on a first face 1140 of the circuit board 1102 and an opposing second face 1142 of the circuit board 1102; generally, components may be disposed on one or both faces 1140 and 1142. Any of the IC packages discussed below with reference to the IC device assembly 1100 may take the form of the example IC package 100 of FIG. 1.

In some examples, the circuit board 1102 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1102. In other examples, the circuit board 1102 may be a non-PCB substrate.

The IC device assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), male and female portions of a socket, an adhesive, an underfill material, and/or any other suitable electrical and/or mechanical coupling structure.

The package-on-interposer structure 1136 may include an IC package 1120 coupled to an interposer 1104 by coupling components 1118. The coupling components 1118 may take any suitable form for the application, such as the forms discussed above with reference to the coupling components 1116. Although a single IC package 1120 is shown in FIG. 11, multiple IC packages may be coupled to the interposer 1104; indeed, additional interposers may be coupled to the interposer 1104. The interposer 1104 may provide an intervening substrate used to bridge the circuit board 1102 and the IC package 1120. The IC package 1120 may be or include, for example, a die (the die 902 of FIG. 9), an IC device (e.g., the IC device 1000 of FIG. 10), or any other suitable component. Generally, the interposer 1104 may spread a connection to a wider pitch or reroute a connection to a different connection. For example, the interposer 1104 may couple the IC package 1120 (e.g., a die) to a set of BGA conductive contacts of the coupling components 1116 for coupling to the circuit board 1102. In the example illustrated in FIG. 11, the IC package 1120 and the circuit board 1102 are attached to opposing sides of the interposer 1104; in other examples, the IC package 1120 and the circuit board 1102 may be attached to a same side of the interposer 1104. In some examples, three or more components may be interconnected by way of the interposer 1104.

In some examples, the interposer 1104 may be formed as a PCB, including multiple metal layers separated from one another by layers of dielectric material and interconnected by electrically conductive vias. In some examples, the interposer 1104 may be formed of an epoxy resin, a fiberglass-reinforced epoxy resin, an epoxy resin with inorganic fillers, a ceramic material, or a polymer material such as polyimide. In some examples, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through-silicon vias (TSVs) 1106. The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art.

The IC device assembly 1100 may include an IC package 1124 coupled to the first face 1140 of the circuit board 1102 by coupling components 1122. The coupling components 1122 may take the form of any of the examples discussed above with reference to the coupling components 1116, and the IC package 1124 may take the form of any of the examples discussed above with reference to the IC package 1120.

The IC device assembly 1100 illustrated in FIG. 11 includes a package-on-package structure 1134 coupled to the second face 1142 of the circuit board 1102 by coupling components 1128. The package-on-package structure 1134 may include a first IC package 1126 and a second IC package 1132 coupled together by coupling components 1130 such that the first IC package 1126 is disposed between the circuit board 1102 and the second IC package 1132. The coupling components 1128, 1130 may take the form of any of the examples of the coupling components 1116 discussed above, and the IC packages 1126, 1132 may take the form of any of the examples of the IC package 1120 discussed above. The package-on-package structure 1134 may be configured in accordance with any of the package-on-package structures known in the art.

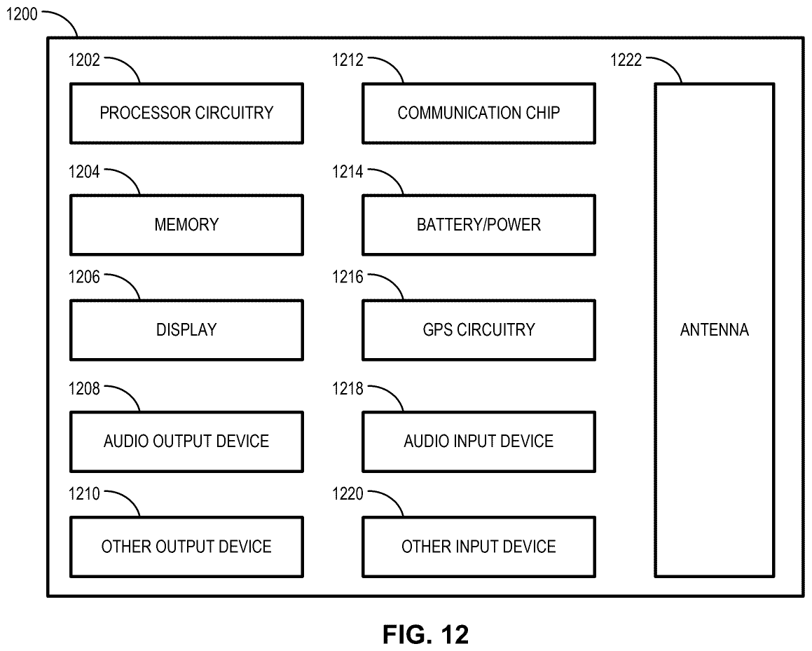

FIG. 12 is a block diagram of an example electrical device 1200 that may include one or more of the example IC package 100. For example, any suitable ones of the components of the electrical device 1200 may include one or more of the device assemblies 1100, IC devices 1000, or dies 902 disclosed herein, and may be arranged in the example IC package 100. A number of components are illustrated in FIG. 12 as included in the electrical device 1200, but any one or more of these components may be omitted or duplicated, as suitable for the application. In some examples, some or all of the components included in the electrical device 1200 may be attached to one or more motherboards. In some examples, some or all of these components are fabricated onto a single system-on-a-chip (SoC) die.

Additionally, in various examples, the electrical device 1200 may not include one or more of the components illustrated in FIG. 12, but the electrical device 1200 may include interface circuitry for coupling to the one or more components. For example, the electrical device 1200 may not include a display 1206, but may include display interface circuitry (e.g., a connector and driver circuitry) to which a display 1206 may be coupled. In another set of examples, the electrical device 1200 may not include an audio input device 1218 (e.g., microphone) or an audio output device 1208 (e.g., a speaker, a headset, earbuds, etc.), but may include audio input or output device interface circuitry (e.g., connectors and supporting circuitry) to which an audio input device 1218 or audio output device 1208 may be coupled.

The electrical device 1200 may include programmable circuitry 1202 (e.g., one or more processing devices). The programmable circuitry 1202 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1200 may include a memory 1204, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1204 may include memory that shares a die with the programmable circuitry 1202. This memory may be used as cache memory and may include embedded dynamic random access memory (eDRAM) or spin transfer torque magnetic random access memory (STT-MRAM).

In some examples, the electrical device 1200 may include a communication chip 1212 (e.g., one or more communication chips). For example, the communication chip 1212 may be configured for managing wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1212 may operate in accordance with other wireless protocols in other examples. The electrical device 1200 may include an antenna 1222 to facilitate wireless communications and/or to receive other wireless communications (such as AM or FM radio transmissions).

In some examples, the communication chip 1212 may manage wired communications, such as electrical, optical, or any other suitable communication protocols (e.g., the Ethernet). As noted above, the communication chip 1212 may include multiple communication chips. For instance, a first communication chip 1212 may be dedicated to shorter-range wireless communications such as Wi-Fi or Bluetooth, and a second communication chip 1212 may be dedicated to longer-range wireless communications such as global positioning system (GPS), EDGE, GPRS, CDMA, WiMAX, LTE, EV-DO, or others. In some examples, a first communication chip 1212 may be dedicated to wireless communications, and a second communication chip 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display 1206 (or corresponding interface circuitry, as discussed above). The display 1206 may include any visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any device that generates an audible indicator, such as speakers, headsets, or earbuds.

The electrical device 1200 may include an audio input device 1218 (or corresponding interface circuitry, as discussed above). The audio input device 1218 may include any device that generates a signal representative of a sound, such as microphones, microphone arrays, or digital instruments (e.g., instruments having a musical instrument digital interface (MIDI) output).

The electrical device 1200 may include GPS circuitry 1216. The GPS circuitry 1216 may be in communication with a satellite-based system and may receive a location of the electrical device 1200, as known in the art.

The electrical device 1200 may include any other output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include any other input device 1220 (or corresponding interface circuitry, as discussed above). Examples of the other input device 1220 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1200 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that reduce the stress experienced by glass cores during loading. Examples disclosed herein include interfaces that reduce stress concentrations in the power delivery regions of glass cores. Examples disclosed herein enable the packaging of power delivery components, such as CMILs, PTHs, and TGVs, and maintain the structural integrity of the glass core. Examples disclosed herein reduce the seware failure rate of glass cores, which increases part yield and decreases manufacturing costs.

Glass cores with embedded power delivery components are disclosed herein. Further examples and combinations thereof include the following:

Example 1 includes an apparatus a glass layer including an opening, a dielectric material within the opening, a first cluster of inductors extending through the dielectric material, and a second cluster of inductors extending through the dielectric material, the second cluster spaced apart from the first cluster, the dielectric material extending continuously from around the first cluster to around the second cluster.

Example 2 includes the apparatus of any preceding example, wherein the opening extends through the glass layer from a first surface of the glass layer to a second surface of the glass layer, the second surface opposite the first surface.

Example 3 includes the apparatus of any preceding example, wherein the opening includes an internal surface and the dielectric material includes an external surface abutting the internal surface.

Example 4 includes the apparatus of any preceding example, further including a glass wall between the first and second clusters, the dielectric material to extend around at least one of an upper end or a lower end of the glass wall.

Example 5 includes the apparatus of any preceding example, further including a transition surface extending between the glass wall and the glass layer.

Example 6 includes the apparatus of any preceding example, wherein the transition surface is a fillet.

Example 7 includes the apparatus of any preceding example, wherein a first upper surface of the dielectric material is flush with a second upper surface of the dielectric material.

Example 8 includes a device comprising a semiconductor die, a substrate supporting the semiconductor die, the substrate including a glass core including a body including an opening, a dielectric material within the opening, a first cluster of inductors extending through the dielectric material, adjacent ones of the inductors in the first cluster a first distance apart, and a second cluster of inductors extending through the dielectric material, a first inductor in the first cluster at least as close to a second inductor in the second cluster as any other inductor in the first cluster is to any inductor in the second cluster, the first inductor spaced a second distance apart from the second inductor, the second distance greater than the first distance, the dielectric material extending continuously between the first inductor and the second inductor.

Example 9 includes the device of any preceding example, wherein the first cluster of inductors and the second cluster are disposed in a row, the row further including a third cluster of inductors offset from the first cluster of inductors and the second cluster of inductors.

Example 10 includes the device of any preceding example, further including a plurality of plated through holes aligned with the third cluster, the plated through holes extending through the dielectric material.

Example 11 includes the device of any preceding example, further including a glass webbing disposed between the first cluster of inductors and the second cluster of inductors.

Example 12 includes the device of any preceding example, wherein the body includes a first outer surface and a second outer surface opposite the first outer surface, the webbing recessed from the first outer surface and the second outer surface.

Example 13 includes the device of any preceding example, further including a curved surface extending between the first outer surface and the glass core.

Example 14 includes the device of any preceding example, wherein the first outer surface is flush with a third outer surface of the glass core.

Example 15 includes the device of any preceding example, wherein the opening includes an internal surface, the dielectric material includes an external surface abutting the internal surface, and the internal surface is straight walled.

Example 16 includes an apparatus including a glass core including a structural portion, a power delivery portion, and an interface between the structural portion and the power delivery portion, the interface including at least one (i) a material interface or (ii) a curved transition surface between a recessed portion of the power delivery portion and an outer surface of the glass core, and a plurality of coaxial metal inductor loop clusters in the power delivery portion.

Example 17 includes the apparatus of any preceding example, wherein the plurality of coaxial metal inductor loop clusters are disposed in a first row and a second row, the first row including a first cluster, a second cluster, and a third cluster, the second cluster offset from the first cluster and the second cluster.

Example 18 includes the apparatus of any preceding example, wherein the outer surface is a first outer surface and a second outer surface of the power delivery portion is flush with the first outer surface.

Example 19 includes the apparatus of any preceding example, wherein the power delivery portion includes a dielectric filler and the recessed portion is aligned with the dielectric filler in a direction normal to the outer surface.

Example 20 includes the apparatus of any preceding example, wherein the structural portion has a first thickness and the recessed portion has a second thickness that is at least 10% of the first thickness. The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus:
a glass layer including an opening;
a dielectric material within the opening;
a first cluster of inductors extending through the dielectric material; and
a second cluster of inductors extending through the dielectric material, the second cluster spaced apart from the first cluster, the dielectric material extending continuously from around the first cluster to around the second cluster.

2. The apparatus of claim 1, wherein the opening extends through the glass layer from a first surface of the glass layer to a second surface of the glass layer, the second surface opposite the first surface.

3. The apparatus of claim 2, wherein the opening includes an internal surface and the dielectric material includes an external surface abutting the internal surface.

4. The apparatus of claim 1, further including a glass wall between the first and second clusters, the dielectric material to extend around at least one of an upper end or a lower end of the glass wall.

5. The apparatus of claim 4, further including a transition surface extending between the glass wall and the glass layer.

6. The apparatus of claim 5, wherein the transition surface is a fillet.

7. The apparatus of claim 1, wherein a first upper surface of the dielectric material is flush with a second upper surface of the dielectric material.

8. A device comprising:
a semiconductor die;
a substrate supporting the semiconductor die, the substrate including:
a glass core including:
a body including an opening;
a dielectric material within the opening;
a first cluster of inductors extending through the dielectric material, adjacent ones of the inductors in the first cluster a first distance apart; and
a second cluster of inductors extending through the dielectric material, a first inductor in the first cluster at least as close to a second inductor in the second cluster as any other inductor in the first cluster is to any inductor in the second cluster, the first inductor spaced a second distance apart from the second inductor, the second distance greater than the first distance, the dielectric material extending continuously between the first inductor and the second inductor.

9. The device of claim 8, wherein the first cluster of inductors and the second cluster are disposed in a row, the row further including a third cluster of inductors offset from the first cluster of inductors and the second cluster of inductors.

10. The device of claim 9, further including a plurality of plated through holes aligned with the third cluster, the plated through holes extending through the dielectric material.

11. The device of claim 9, further including a glass webbing disposed between the first cluster of inductors and the second cluster of inductors.

12. The device of claim 11, wherein the body includes a first outer surface and a second outer surface opposite the first outer surface, the webbing recessed from the first outer surface and the second outer surface.

13. The device of claim 12, further including a curved surface extending between the first outer surface and the glass core.

14. The device of claim 12, wherein the first outer surface is flush with a third outer surface of the glass core.

15. The device of claim 9, wherein the opening includes an internal surface, the dielectric material includes an external surface abutting the internal surface, and the internal surface is straight walled.

16. An apparatus including:
a glass core including:
a structural portion;
a power delivery portion; and
an interface between the structural portion and the power delivery portion, the interface including at least one (i) a material interface or (ii) a curved transition surface between a recessed portion of the power delivery portion and an outer surface of the glass core; and
a plurality of coaxial metal inductor loop clusters in the power delivery portion.

17. The apparatus of claim 16, wherein the plurality of coaxial metal inductor loop clusters are disposed in a first row and a second row, the first row including:
a first cluster;
a second cluster; and
a third cluster, the second cluster offset from the first cluster and the second cluster.

18. The apparatus of claim 16, wherein the outer surface is a first outer surface and a second outer surface of the power delivery portion is flush with the first outer surface.

19. The apparatus of claim 16, wherein the power delivery portion includes a dielectric filler and the recessed portion is aligned with the dielectric filler in a direction normal to the outer surface.

20. The apparatus of claim 19, wherein the structural portion has a first thickness and the recessed portion has a second thickness that is at least 10% of the first thickness.
